(19) United States
(12) Patent Application Publication
(10) Pub. No.: US 2007/0206425 A1
(43) Pub. Date: Sep. 6, 2007

(54) Semiconductor memory device

(75) Inventor: Kazuhiro Takahashi, Kawasaki (JP)

Correspondence Address: ARENT FOX PLLC, 1050 CONNECTICUT AVENUE, N.W., SUITE 400, WASHINGTON, DC, 20036, US

(73) Assignee: FUJITSU LIMITED

(21) Appl. No.: 11/487,341

(22) Filed: Jul. 17, 2006

(30) Foreign Application Priority Data
Mar. 2, 2006 (JP) 2006-056435

(51) Int. Cl. G11C 7/10

(52) U.S. Cl. 365/189.06

(57) ABSTRACT

A semiconductor memory device capable of suppressing variation in a threshold voltage of a cell. A write controller monitors a write level of a cell and compares the write level with a predetermined set level (a predetermined current value) by measuring, for example, a bit line current during a write operation. Further, the write controller, when the write level reaches the set level, outputs a control signal for causing completion of the write operation. Therefore, variation in a threshold voltage of a cell after the write operation is suppressed.

### CROSS-REFERENCE TO RELATED APPLICATIONS

This application is based upon and claims the benefits of priority from the prior Japanese Patent Application No. 2006-056435, filed on Mar. 2, 2006, the entire contents of which are incorporated herein by reference.

### BACKGROUND OF THE INVENTION

1. Field of the Invention

The present invention relates to a semiconductor memory device, and more particularly, to a semiconductor memory device having a nonvolatile memory cell such as a flash memory cell.

2. Description of the Related Art

A flash memory is employed as one of nonvolatile memories capable of storing information even if a power supply is turned off.

The flash memory has a floating gate buried in a gate insulating film of Insulated Gate Field-Effect Transistors (IGFET). In the flash memory, information is written by accumulating in the floating gate an electric charge which indicates memory information. Further, in the flash memory, the condition in which the charge is accumulated in the floating gate is set to 0 and the condition in which no charge is accumulated in the floating gate is set to 1.

FIG. 6 is a schematic diagram illustrating a write operation to a cell in a conventional flash memory.

During the writing, a voltage V_{WL} is applied to a word line WL of a selected flash memory cell (hereinafter, simply referred to as a cell) 50 through a word line control circuit (not shown). When the voltage V_{WL} exceeds a threshold voltage of the cell 50, a bit line current I_{BL} starts to flow through a bit line BL by a voltage V_{d}. At the start of the flowing, the write operation to the cell 50 is initiated and the charge is accumulated in the cell 50. As a result, the threshold voltage rises up and the bit line current I_{BL} starts to decrease.

FIG. 7 shows a relationship between a voltage pulse applied to a word line during the writing and a bit line current.

In a conventional flash memory, the voltage V_{WL} applied to the word line WL has a predetermined pulse width as shown in the figure. Further, the application of the voltage V_{WL} is stopped at a predetermined timing Φ to complete the write operation. However, due to variation in characteristics of each cell 50 in a memory cell array, the bit line currents I_{BL1}, and I_{BL2} differ from cell to cell as shown in the figure. As a result, the threshold voltages after completion of the write operation sometimes vary.

FIG. 8 shows a distribution of a threshold voltage at the completion of the write operation to a cell in a conventional flash memory.

In FIG. 8, the longitudinal axis shows the number of cells and the horizontal axis shows the threshold voltage V_{TH}.

As shown in the figure, the threshold voltage V_{TH} of a cell, when a pulse width of and the number of pulses of the voltage V_{WL} as shown in FIG. 7 are adjusted, increases more than a write decision value to cause a write-state. However, the threshold voltage V_{TH} shows a distribution due to the above-described variation in characteristics.

The variation in characteristics of each cell 50 includes that in a film thickness, a line width and a thermal history. In addition thereto, also the variation in factors such as a temperature, a voltage, a time and a contact resistance varying in each write test causes the distribution of the threshold voltage V_{TH}.

In a nonvolatile memory such as a flash memory, an accelerated test such as aging is performed to guarantee a retention characteristic of write information.

The aging is a method for causing accelerated deterioration of a potential defective cell which may early become defective due to deterioration with time and for preventing the defective cell from coming on the market. Specifically, a cell of which the threshold voltage V_{TH} decreases below a write decision value shown in FIG. 8 is screened after the aging.

In addition, for example, Japanese Unexamined Patent Publication No. 2004-334994 discloses a technology where when the threshold voltage becomes negative due to an over-erasure during erasure of cell data in a flash memory, the threshold voltage is written back to an appropriate erased state.

However, when a threshold voltage of the cell after a write operation has a distribution as shown in FIG. 8, the following problems may occur during an accelerated test such as aging.

FIG. 9 shows a change in the threshold voltage of a cell before and after the aging.

Herein, the cells 51 and 52 are ones where by the aging, write information is attenuated (the threshold voltage V_{TH} decreases) as indicated by arrows in the figure. The cells 51 and 52 have the same attenuation.

The threshold voltage V_{TH} of the cell 51 positioning at the left bottom of the distribution decreases below the write decision value by the aging. Therefore, the cell 51 can be screened. On the other hand, the threshold voltage V_{TH} of the cell 52 positioning at the right bottom of the distribution does not decrease below the write decision value although the cell 52 has the same attenuation as that of the cell 51. Therefore, the cell 52 cannot be screened.

As described above, the threshold voltage V_{TH} of a cell after the write operation to a cell in the conventional flash memory varies depending on the test environment or use environment such as a pulse width of or the number of pulses of a voltage applied to a word line during the write operation. Therefore, there is also considered a case where the threshold voltage V_{TH} of the cell 52 moves to the left bottom of the distribution in FIG. 9 after bringing the cell 52 to the market. In that case, there is a problem that since the threshold voltage V_{TH} of the cell 52 decreases below the write decision value due to the deterioration, the cell 52 becomes defective.

Further, there is a problem that since the threshold voltage V_{TH} of the cell varies in a conventional flash memory, a write test of a plurality of samples cannot be performed at the same time.

FIG. 10 is a block diagram showing an outline of the write test.

FIG. 10 shows a case of performing a write test to flash memories 54 and 55 by the use of an Integrated Circuit (IC) tester 53. As described above, the threshold voltage V_{TH} varies from cell to cell. Therefore, there occurs a case where the number of pulses necessary for the write differs from sample to sample. For example, the flash memory 54 requires three pulses and the flash memory 55 requires two pulses. On this occasion, when three pulses are simultaneously supplied to both of the flash memories 54 and 55 using the IC tester 53, the flash memory 55 is over-written. Therefore, the IC tester 53 must perform a measurement on each sample, and as a result, the test cost is expensive.

### SUMMARY OF THE INVENTION

In view of the foregoing, it is an object of the present invention to provide a semiconductor memory device capable of suppressing variation in a threshold voltage of a cell.

To accomplish the above object, according to one aspect of the present invention, there is provided a semiconductor memory device, comprising: a memory cell array section having a plurality of nonvolatile memory cells arranged in a matrix form; and a write controller which, when a write level of the nonvolatile memory cell reaches a predetermined set level during a write operation, outputs a control signal for causing completion of the write operation.

The above and other objects, features and advantages of the present invention will become apparent from the following description when taken in conjunction with the accompanying drawings which illustrate preferred embodiments of the present invention by way of example.

### BRIEF DESCRIPTION OF THE DRAWINGS

FIG. 1 shows a configuration of a semiconductor memory device according to a first embodiment.

FIG. 2 is a configuration view showing an essential part of the semiconductor memory device of the first embodiment for illustrating a write operation.

FIGS. 3A and 3B show a word line voltage and bit line current during the write operation to cells having different characteristics.

FIG. 4 shows a distribution of a threshold voltage of a cell after completion of a write operation to a cell and a change in a threshold voltage of a cell before and after aging.

FIG. 5 shows a configuration of a semiconductor memory device according to a second embodiment.

FIG. 6 is a schematic diagram illustrating a write operation to a cell in a conventional flash memory.

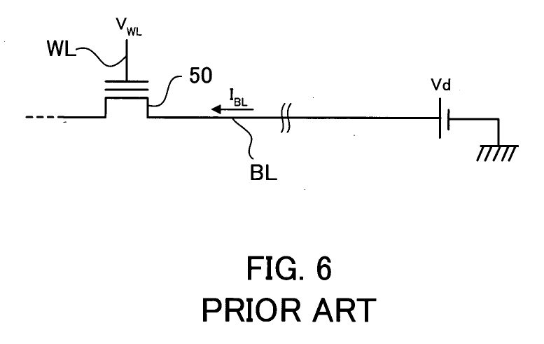

FIG. 7 shows a relationship between a voltage pulse applied to a word line during writing and a bit line current.

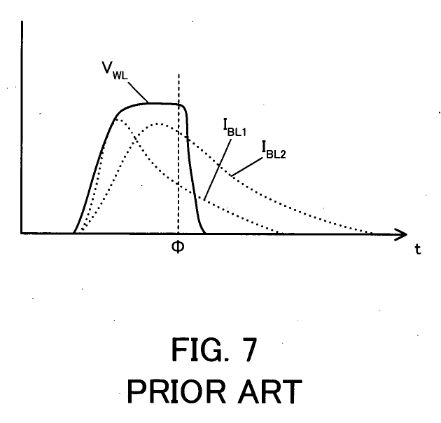

FIG. 8 shows a distribution of a threshold voltage at completion of a write operation to a cell in a conventional flash memory.

FIG. 9 shows a change in a threshold voltage of a cell before and after aging.

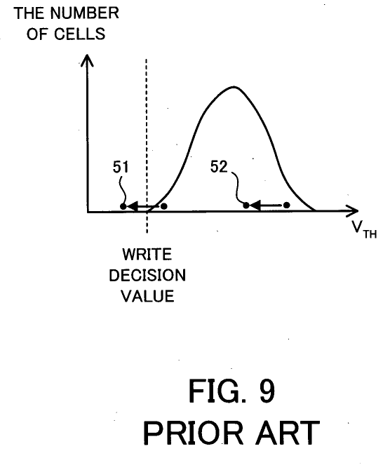

FIG. 10 is a block diagram showing an outline of a write test.

### DESCRIPTION OF THE PREFERRED EMBODIMENTS

Preferred embodiments of the present invention will be described in detail below with reference to the accompanying drawings, wherein like reference numerals refer to like elements throughout.

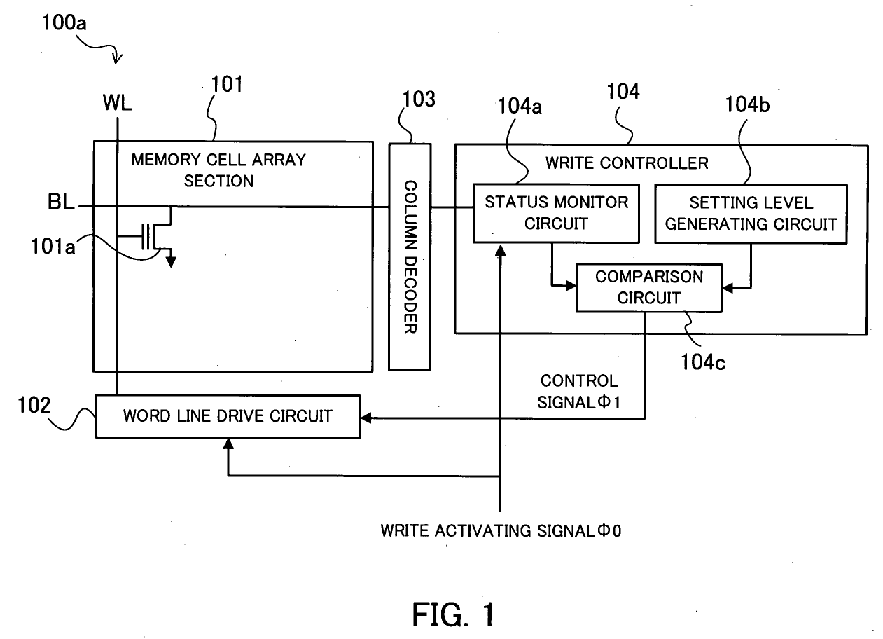

FIG. 1 shows a configuration of a semiconductor memory device according to a first embodiment.

A semiconductor memory device 100a according to the first embodiment is, for example, a flash memory. The device 100a comprises a plurality of cells 101a (only one cell is shown in the figure) disposed in a matrix form, a word line WL and bit line BL connected thereto, a word-line drive circuit 102 for driving the word line WL, a column decoder 103 for selecting the bit line BL, and a write controller 104.

The write controller 104 has a function, when a write level of the cell 101a reaches a certain set level during a write operation to the cell 101a, of outputting a control signal Φ1 for causing completion of the write operation. Specifically, the write controller 104 has a status monitor circuit 104a which monitors a write level of the cell 101a, a set level generating circuit 104b which outputs a predetermined set level and a comparison circuit 104c which compares the monitored write level with the predetermined set level.

The status monitor circuit 104a monitors a write level of the cell 101a during a write operation by monitoring, for example, a current value of the bit line BL connected to the cell 101a.

The set level generating circuit 104b outputs a predetermined set level (e.g., in a case of a flash memory, a write state level resulting from adding a predetermined margin to a threshold between “1” as a non-write state and “0” as a write state). The set level is expressed, for example, by a predetermined current value and further can be changed into a desired value.

The comparison circuit 104c compares a write level of the cell 101a monitored by the status monitor circuit 104a and a set level outputted from the set level generating circuit 104b. Further, when the write level reaches the set level, the circuit 104c outputs the control signal Φ1 for causing completion of the write operation. In the semiconductor memory device 100a according to the first embodiment, the circuit 104c supplies the control signal Φ1 to the word-line drive circuit 102 and inactivates a word line WL connected to the cell 101a to thereby cause completion of the write operation.

The write controller 104 is connected to the column decoder 103 for selecting the bit line BL and monitors a write level of the cell 101a connected to the bit line BL selected by the column decoder 103. Therefore, the write controller 104 need not be provided for each of the bit lines BL, so that increase in a circuit area can be prevented.

The write operation in the semiconductor memory device 100a according to the first embodiment will be described below.

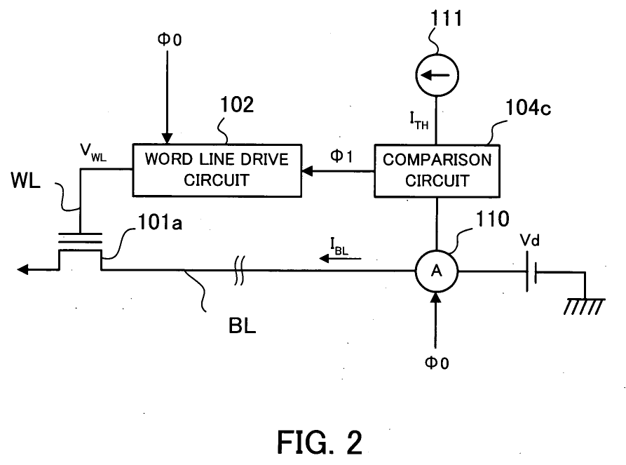

FIG. 2 is a configuration view showing an essential part of the semiconductor memory device of the first embodiment for illustrating the write operation.

Herein, there is shown a case of using as the status monitor circuit 104a a current measuring circuit 110 for monitoring a write level by measuring a bit line current I_{BL} and using a constant current source 111 as the set level generating circuit 104b. In addition, a memory circuit (e.g., a flash memory) which stores a constant current value I_{TH} may be used in place of the constant current source 111.

When the write activating signal Φ0 is inputted into the word line drive circuit 102 to cause initiation of a write operation, the word line drive circuit 102 applies a high voltage V_{WL} to the word line WL connected to the cell 101a with a specified address. Further, the predetermined voltage V_{d} is applied to the bit line BL specified by the column decoder 103 in FIG. 1. As a result, the charge is written in the cell 101a. On the other hand, when detecting that a write operation is initiated by the write activating signal Φ0, the current measuring circuit 110 starts monitoring of a write level of the cell 101a expressed by the bit line current I_{BL} of the bit line BL.

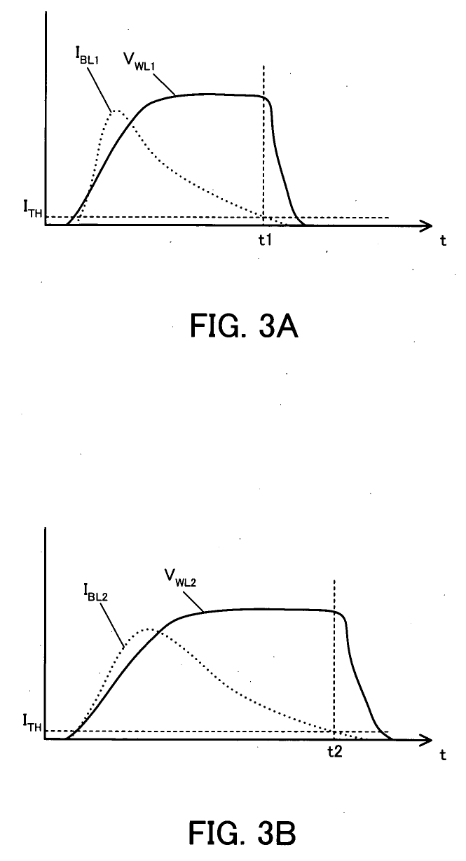

FIGS. 3A and 3B show a word line voltage and bit line current during the write operation to cells having different characteristics.

For example, the current measuring circuit 110 measures in some cell 101a a bit line current I_{BL1} as shown in FIG. 3A. The comparison circuit 104c compares the measured bit line current I_{BL1} with the current value I_{TH} outputted from the constant current source 111. Further, at the timing (t1 shown in FIG. 3A) when the bit line current I_{BL1} matches the current value I_{TH}, the circuit 104c outputs to the word line drive circuit 102 the control signal Φ1 for inactivating the word line WL. In addition, at the rising up of the bit line current I_{BL1}, the bit line current I_{BL1} matches the current value I_{TH} to cause output of the control signal Φ1. In order to prevent the output of the control signal Φ1, the comparison by the comparison circuit 104c is started after a predetermined time from the initiation of a write operation. Further, the measurement of the bit line current I_{BL1} by the current measuring circuit 110 may be started after a predetermined time from the initiation of a write operation.

Thus, when the charge is written in the cell 101a during the write operation, the threshold voltage V_{TH} rises up as well as the bit line current I_{BL1} decreases. At the timing t1 when the current I_{BL1} reaches the current value I_{TH}, the word line WL is inactivated (a voltage V_{WL1} falls down) to cause completion of the write operation.

Also in the case where due to variation in characteristics, the cell 101a having a characteristic of a bit line current I_{BL2} different from that in FIG. 3A is found as shown in FIG. 3B, the same operation is performed. That is, at the timing t2 when the bit line current I_{BL2} decreases and reaches the current value I_{TH}, the word line WL is inactivated (a voltage V_{WL2} falls down) to cause completion of the write operation.

That is, according to the semiconductor memory device 100a of the present embodiment, even if the characteristics vary in each of the cells 101a, when the write level reaches the set level expressed by the current value I_{TH} of the constant current source 111, the write operation is completed. Thus, the variation in the threshold voltage V_{TH} can be suppressed.

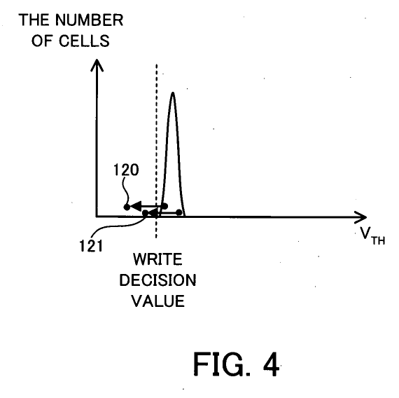

FIG. 4 shows a distribution of the threshold voltage of the cell after completion of a write operation to a cell and a change in the threshold voltage of a cell before and after the aging.

Cells 120 and 121 are ones in which due to aging, write information is attenuated (the threshold voltage V_{TH} decreases) as indicated by arrows in the figure. The cells 120 and 121 have the same attenuation.

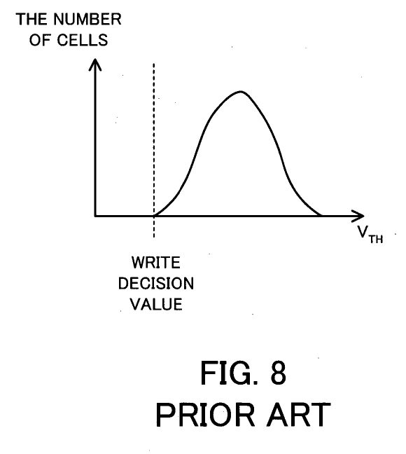

As shown in the figure, in the semiconductor memory device 100a of the present embodiment, the variation in the threshold voltage V_{TH} after the write operation is suppressed and therefore, the distribution of the threshold voltage V_{TH} becomes sharper than a conventional one as shown in FIG. 8. Accordingly, in the cell 120 positioning at the left bottom of the distribution as well as in the cell 121 positioning at the right bottom of the distribution, the threshold voltages V_{TH} can be decreased below the write decision value by carrying out aging. Therefore, both the cells can be screened. As a result, the accuracy of the reliability test is improved, so that a defective cell can be prevented from coming on the market.

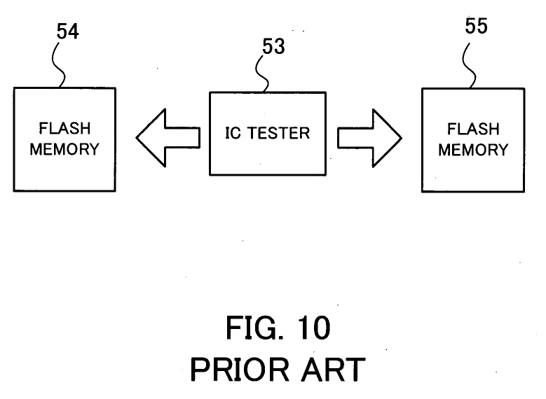

Further, since the variation in the threshold voltage V_{TH} is reduced, the voltage V_{WL} applied to the word line WL can be simultaneously applied to a plurality of samples in performing the write test. Further, since the write controller 104 automatically performs inactivation of the word line WL, an over-write can be prevented. Further, the IC tester 53 as shown in FIG. 10 can simultaneously perform the write test on a plurality of semiconductor memory devices 100a as samples. As a result, the test cost can be largely cut.

In the above, there is described a case where the write controller 104 monitors a bit line current as a write level. Further, the controller 104 may monitor the threshold voltage V_{TH} of the cell 101a. In this case, the controller 104 compares the threshold voltage V_{TH} with a predetermined set level (e.g., a voltage level resulting from adding a margin to the write decision value) and, when the threshold voltage V_{TH} reaches the set level, outputs the control signal Φ1 for causing completion of the write operation.

Further, in place of a flash memory cell, a nonvolatile memory cell such as a NROM (R) cell or a ferroelectric memory cell may be used for the cell 101a.

Next, a semiconductor memory device according to a second embodiment will be described.

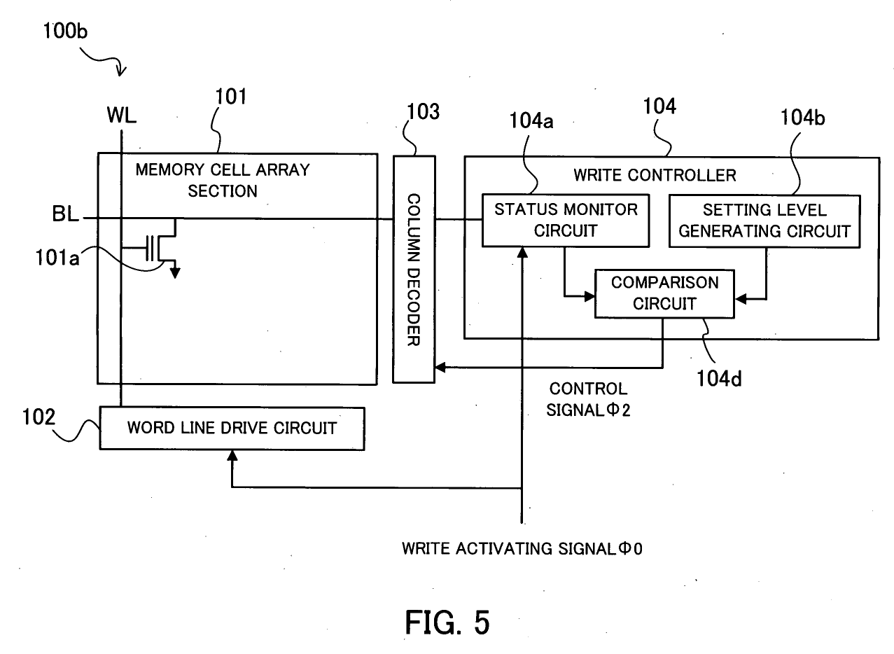

FIG. 5 shows a configuration of the semiconductor memory device according to the second embodiment.

In the diagram, the same elements as those in the semiconductor memory device 100a of the first embodiment are indicated by the same reference numerals as in the device 100a and the description is omitted.

In the above-described semiconductor memory device 100a according to the first embodiment, the comparison circuit 104c, when the write level reaches a predetermined set level, outputs the control signal Φ1 to the word line drive circuit 102 and inactivates the word line WL to thereby cause completion of the write operation.

To the contrary, in the semiconductor memory device 100b according to the second embodiment, the comparison circuit 104d, when the write level reaches a predetermined set level, outputs a control signal Φ2 to the column decoder 103 and inactivates the bit line BL to thereby cause completion of the write operation. The other operations of the device 100b are the same as those of the semiconductor memory device 100a according to the first embodiment.

Also by using such a semiconductor memory device 100b according to the second embodiment, the same effect as that of the semiconductor memory device 100a according to the first embodiment can be obtained.

According to the semiconductor memory device of the present invention, the write controller, when the write level of a cell reaches a predetermined set level during the write operation to the cell, outputs the control signal for causing completion of the write operation. Therefore, variation in the threshold voltage of a cell after the write operation can be suppressed.

The foregoing is considered as illustrative only of the principles of the present invention. Further, since numerous modifications and changes will readily occur to those skilled in the art, it is not desired to limit the invention to the exact construction and applications shown and described, and accordingly, all suitable modifications and equivalents may be regarded as falling within the scope of the invention in the appended claims and their equivalents.

What is claimed is:

1. A semiconductor memory device, comprising:
a memory cell array section having a plurality of nonvolatile memory cells disposed in a matrix form; and
a write controller which, when a write level of the nonvolatile memory cell reaches a predetermined set level during a write operation, outputs a control signal for causing completion of the write operation.

2. The semiconductor memory device according to claim 1, wherein:
the write level is expressed by a current value of a bit line connected to the nonvolatile memory cell during the write operation;
the set level is expressed by a predetermined current value; and
the write controller, when the current value of the bit line decreases and reaches the predetermined current value, outputs the control signal.

3. The semiconductor memory device according to claim 1, wherein:
the write controller is connected to a selection circuit for selecting a bit line connected to the nonvolatile memory cell and monitors during the write operation the write level of the nonvolatile memory cell connected to the bit line selected by the selection circuit.

4. The semiconductor memory device according to claim 1, wherein:
the write controller, when the write operation is initiated, starts comparison between the write level and the set level after a predetermined time.

5. The semiconductor memory device according to claim 1, wherein:
the control signal is a signal for inactivating a word line connected to the nonvolatile memory cell.

6. The semiconductor memory device according to claim 1, wherein:
the control signal is a signal for inactivating a bit line connected to the nonvolatile memory cell.

7. The semiconductor memory device according to claim 1, wherein:
the write controller comprises:
a status monitor circuit which monitors the write level;
a set level generating circuit which outputs the set level; and
a comparison circuit which compares the monitored write level with the set level and which, when the write level reaches the set level, outputs the control signal.

8. The semiconductor memory device according to claim 7, wherein:
the comparison circuit, when the write operation is initiated, starts comparison between the write level and the set level after a predetermined time.

9. The semiconductor memory device according to claim 7, wherein:
the status monitor circuit monitors a current value of a bit line connected to the nonvolatile memory cell;
the set level generating circuit outputs a predetermined current value; and
the comparison circuit compares the current value of the bit line with the predetermined current value and, when the current value of the bit line decreases and reaches the predetermined current value, outputs the control signal.

10. The semiconductor memory device according to claim 9, wherein:
the status monitor circuit is a current measuring circuit.

11. The semiconductor memory device according to claim 9, wherein:
the set level generating circuit is a constant current source.

12. The semiconductor memory device according to claim 9, wherein:
the set level generating circuit is a memory circuit which stores a set current value.
